(19) United States
(12) Patent Application Publication
(10) Pub. No.: US 2014/0374742 A1
(43) Pub. Date: Dec. 25, 2014

(54) LIGHT EMITTING DISPLAY

(71) Applicant: HON HAI PRECISION INDUSTRY CO., LTD., New Taipei (TW)

(72) Inventor: JIAN-SHIHN TSANG, Tu-Cheng (TW)

(73) Assignee: HON HAI PRECISION INDUSTRY CO., LTD., New Taipei (TW)

(21) Appl. No.: 14/221,207

(22) Filed: Mar. 20, 2014

(30) Foreign Application Priority Data
Jun. 25, 2013 (TW) 102122611

(51) Int. Cl. H01L 25/16; H01L 27/15; H01L 27/12

(52) U.S. Cl. CPC H01L 25/167; H01L 27/1225; H01L 27/156
USPC 257/43

(57) ABSTRACT

An exemplary light emitting display includes a nitride light emitting diode formed on a first substrate and a thin film transistor formed on a second substrate. The first substrate and the second substrate are arranged face-to-face, and the first substrate is spaced from the second substrate. The nitride light emitting diode electrically connects with the thin film transistor. The thin film transistor comprises an active layer, and the active layer of the thin film transistor deviates from the light path of the nitride light emitting diode.

### BACKGROUND

1. Technical Field

This disclosure generally relates to light emitting displays, and particularly to a light emitting display comprising a nitride light emitting diode directly connecting with a thin film transistor.

2. Description of Related Art

A typical active matrix organic light emitting display (AMOLED) includes a plurality of organic light emitting elements functioning as light sources. However, in a manufacturing process of the active matrix organic light emitting display, the organic light emitting materials are prone to be affected by environmental factors, such as moisture, which cause the organic materials to be deteriorated. Therefore, the manufacturing process of the active matrix organic light display needs to be performed in a vacuum environment to avoid the deterioration of the organic materials, resulting in a complicated manufacturing process. In addition, the deterioration of the organic light emitting materials shortens the service life of the active matrix organic light displays.

What is needed, therefore, is a light emitting display which can overcome the above-described shortcoming.

### BRIEF DESCRIPTION OF THE DRAWINGS

FIG. 1 is a cross-sectional view of a light emitting display according to an exemplary embodiment of the present disclosure.

FIG. 2 is a cross-sectional view of a light emitting display according to a second embodiment of the present disclosure.

FIG. 3 is a cross-sectional view of a light emitting display according to a third embodiment of the present disclosure.

FIG. 4 is a cross-sectional view of a light emitting display according to a fourth embodiment of the present disclosure.

### DETAILED DESCRIPTION

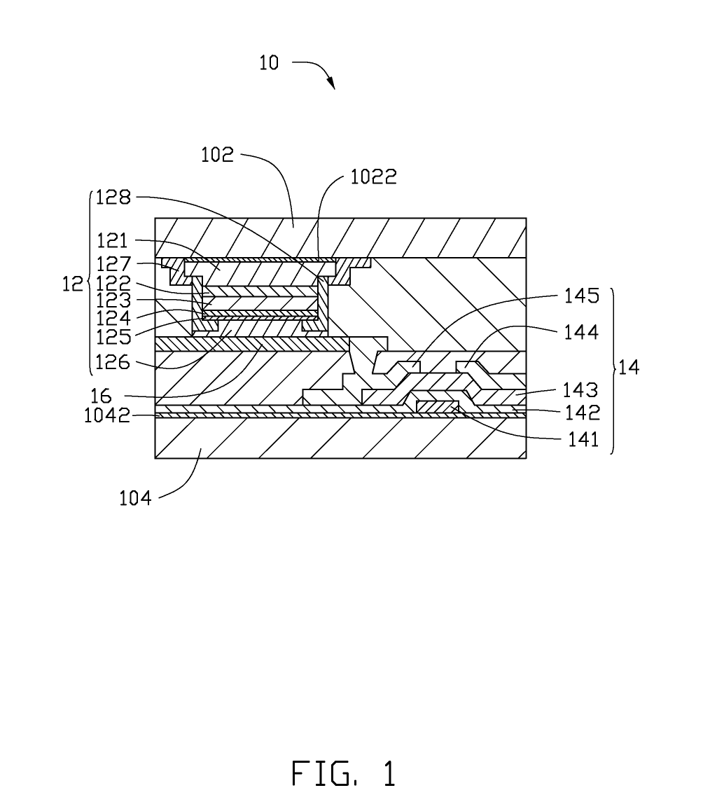

Referring to FIG. 1, a light emitting display 10 in accordance with a first embodiment of the present disclosure is provided.

The light emitting display 10 includes a nitride light emitting diode 12 formed on a first substrate 102, a thin film transistor 14 formed on a second substrate 104 and a connecting layer 16 electrically connecting the nitride light emitting diode 12 with the thin film transistor 14.

The first substrate 102 and the second substrate 104 are made of sapphire, Si, silicon on glass (SOG), glass, GaN, ZnO, or plastic. In this embodiment, the first substrate 102 is made of sapphire or SOG, and the second substrate 104 is made of glass. The first substrate 102 and the second substrate 104 are arranged face-to-face, and the first substrate 102 is spaced from the second substrate 104. The nitride light emitting diode 12 and the thin film transistor 14 are located between the first substrate 102 and the second substrate 104. A first buffer layer 1022 is formed on the first substrate 102. The nitride light emitting diode 12 is formed on the first buffer layer 1022. A second buffer layer 1042 is formed on the second substrate 104. The thin film transistor 14 is formed on the second buffer layer 1042. The first buffer layer 1022 and the second buffer layer 1042 each are made of electrically insulating material. The first buffer layer 1022 is made of low temperature AlGaInN (LT-AlGaInN) or SiC or a combination thereof. The second buffer layer 1042 is made of SiOₓ, SiNₓ, SiON, HfOₓ, AlOₓ, TaOₓ, or BaSrTiOₓ.

The nitride light emitting diode 12 includes an n-type semiconductor layer 121 formed on the first buffer layer 1022, a light emitting layer 122 formed on the n-type semiconductor layer 121, a p-type semiconductor layer 123 formed on the light emitting layer 122, a contact layer 124 formed on the p-type semiconductor layer 123, and a current spreading layer 125 formed on the contact layer 124. A p-type electrode 126 is formed on the current spreading layer 125. An n-type electrode 127 is formed at a lateral side of the n-type semiconductor layer 121, and contacts with the n-type semiconductor layer 121. An insulation layer 128 is formed between the n-type electrode 127 and the p-type electrode 126. The insulation layer 128 extends along a thickness direction of the nitride light emitting diode 12, and electrically insulates the n-type electrode 127 from the p-type electrode 126. The contact layer 124 is an ohmic contact layer. The contact layer 124 and the current spreading layer 125 cooperatively help spread of current into the n-type semiconductor layer 121 to increase the lighting efficiency of the nitride light emitting diode 12. In this embodiment, the nitride light emitting diode 12 emits light with a wavelength ranging from 300 nm to 550 nm. The light emitting layer 122 is made of AlₓGa_{y}In_{(1-x-y)}N (0≦x≦1, 0≦y≦1).

The thin film transistor 14 is located at a lateral side of the nitride light emitting diode 12 and includes a gate electrode 141, a source electrode 144 and a drain electrode 145. The gate electrode 141 is mounted on the second buffer layer 1042. An insulation layer 142 is formed on the gate electrode 141. An active layer 143 is formed on the insulation layer 142. The source electrode 144 and the drain electrode 145 are formed on the active layer 143, and are located at opposite sides of the active layer 143. The insulation layer 142 is made of SiOₓ, SiNₓ, SiON, HfOₓ, AlOₓ, TaOₓ, or BsSrTiOₓ. The active layer 143 is a photosensitive semiconductor active layer, which is made of oxide semiconductor. The photosensitive semiconductor active layer comprises at least one element of In, Ca, Al, Zn, Cd, Ca, Mo, Sn, Hf, Cu, Ti, Ba or Zr. The photosensitive semiconductor active layer is made of InGaZnO, InZnHfO, InZnZrO, InZnSnO, InZnO, or AlInZnO. The source electrode 144 and the drain electrode 145 are metal electrodes, oxide conductive electrodes, or a combination of metal electrodes and oxide conductive electrodes.

The connecting layer 16 is an electrically conductive connecting layer. The connecting layer 16 is formed between the nitride light emitting diode 12 and the thin film transistor 14, and is used to electrically connect the nitride light emitting diode 12 with the thin film transistor 14. The p-type electrode 126 of the nitride light emitting diode 12 electrically connects with one portion of the connecting layer 16, and the source electrode 144 or the drain electrode 145 of the thin film transistor 14 electrically connects with another portion of the connecting layer 16, whereby the nitride light emitting diode 12 electrically connects with the thin film transistor 14 through the connecting layer 16.

In this embodiment, the nitride light emitting diode 12 is located on the connecting layer 16, and the thin film transistor 14 is located at a lateral side of the connecting layer 16, such that, the nitride light emitting diode 12 is not aligned with the thin film transistor 14 along a thickness direction of the light emitting display 10. That is, the thin film transistor 14 deviates from the light path of the nitride light emitting diode 12. Because the active layer 143 is not located at the light path of the nitride light emitting diode 12, the active layer 143 of the thin film transistor 14 will not be directly illuminated by the light emitted from the nitride light emitting diode 12, whereby the possibility of change of electrical characteristics of the active layer 143 due to the illumination of the nitride light emitting diode 12 can be significantly reduced.

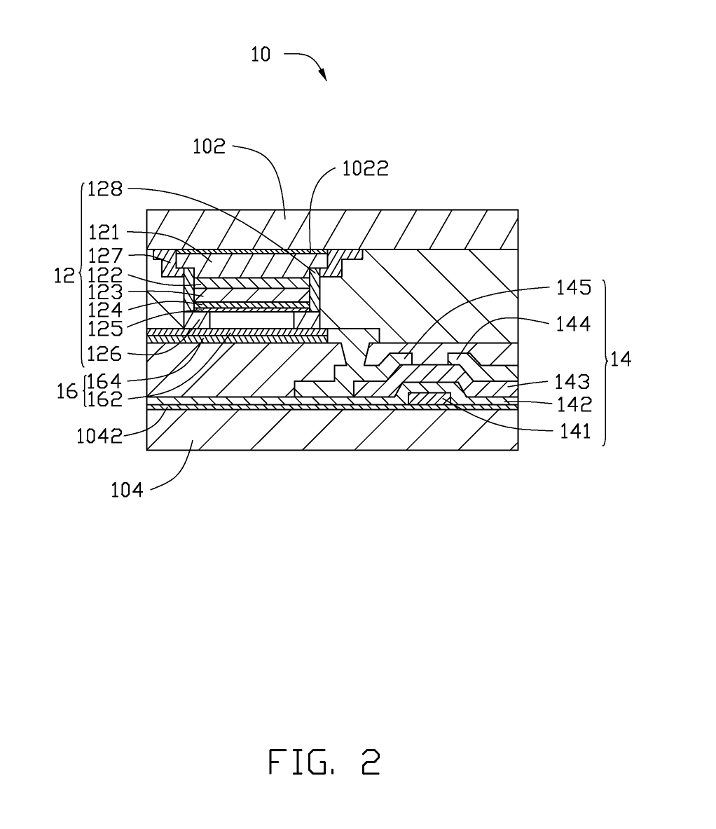

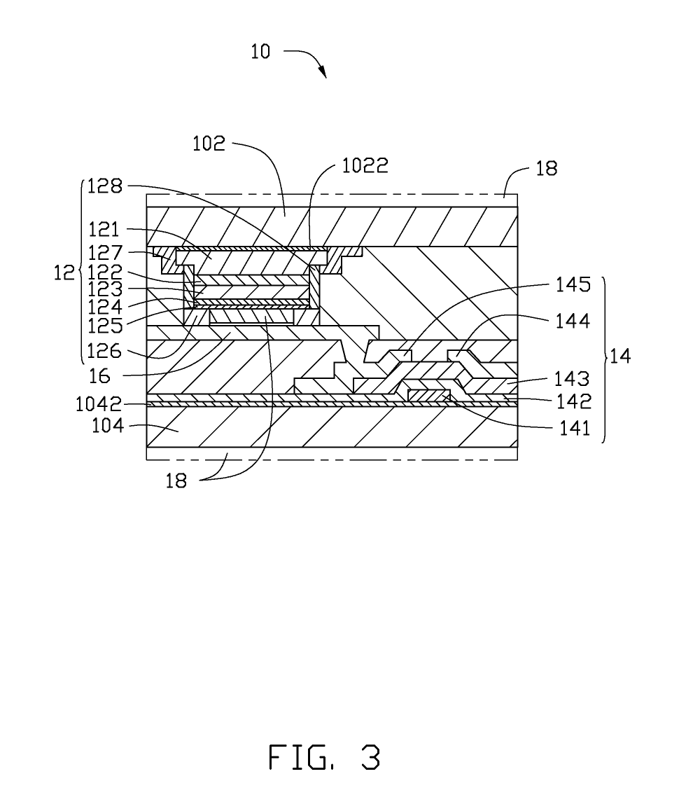

The connecting layer 16 is made of metal, conductive oxides, conductive glue, solder, or a combination thereof. That is, the connecting layer 16 may be a multilayer structure. As shown in FIG. 2, the multilayer structure comprises a metal layer 162 and a transparent conductive oxide layer 164. The metal layer 162 is made of In, Ca, Al, Zn, Cr, Ni, Mo, Sn, Ag, Au, Cu, Ti, Bi, Co, or an alloy thereof. The transparent conductive oxide 164 is made of InSnO, ZnSnO, InZnO, AlZnO, InZnSnO, InGaZnO, InZnHfO, or InZnZrO. In alternative embodiments, the connecting layer 16 is made of silver colloid, SnBi, SnBiCu, SnBiTe, SnBiSe, BiSbTe, BiTeSe, or SnAgCu. Further, in alternative embodiments, the connecting layer 16 and the source electrode 144 or the drain electrode 145 can be formed as a single piece. As shown in FIG. 3, the connecting layer 16 and the drain electrode 145 are made as a single piece.

The light emitting diode display 10 further includes a phosphor layer 18. The phosphor layer 18 can be arranged inside or outside of the light emitting display 10. When the phosphor layer 18 is arranged inside of the light emitting display 10, the phosphor layer 18 is preferably formed between the current spreading layer 125 of the nitride light emitting diode 12 and the connecting layer 16 (shown in FIG. 3), and the p-type electrode 126 is located at opposite ends of the current spreading layer 125 and connects with the connecting layer 16.

Referring to FIG. 3, as shown in dotted lines, when the phosphor layer 18 is arranged outside of the light emitting display 10, the phosphor layer 18 can be located at an outer surface of the first substrate 102, or the phosphor layer 18 can be located at an outer surface of the second substrate 104. The phosphor layer 18 is located at a light path of the nitride light emitting diode 12 to absorb the light emitted from the nitride light emitting diode 12, and then converts the light to another light with another wavelength. The phosphor 18 is excited by primary light emitted from the nitride light emitting diode 12 to emit secondary light with a different color which mixes with the primary light to generate white light.

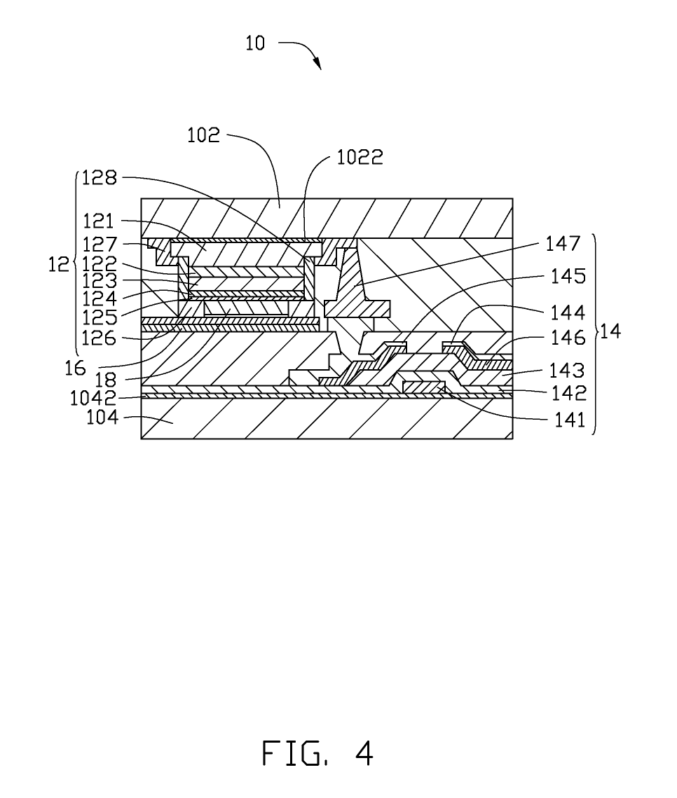

Referring to FIG. 4, at least one of the source electrode 144 and the drain electrode 145 of the thin film transistor 14 includes a metal electrode 146. The metal electrode 146 is located under the source electrode 144 and the drain electrode 145 and used to protect the active layer 143 of the thin film transistor 14 from being irradiated by the light emitted from the nitride light emitting diode 12 In addition, at least one of the source electrode 144 and the drain electrode 145 comprises a metal column 147. The metal column 147 electrically connects with one of the source electrode 144 and the drain electrode 145, and also electrically connects with one of the p-type electrode 126 and the n-type electrode 127. Furthermore, the metal column 147 protects the active layer 143 of the thin film transistor 14 from being irradiated by the light emitted from the nitride light emitting diode 12.

According to the light emitting display of this disclosure, because of the material properties of the nitride light emitting diode 12, the problem of degradation of organic materials in the manufacturing process of light emitting display can be effectively avoided. In addition, because the nitride light emitting diode 12 electrically connects with the thin film transistor 14 via the connecting layer 16 or the metal column 147, the manufacturing process of light emitting display is simplified.

It is to be understood that the above-described embodiments are intended to illustrate rather than limit the disclosure. Variations may be made to the embodiments without departing from the spirit of the disclosure as claimed. The above-described embodiments illustrate the scope of the disclosure but do not restrict the scope of the disclosure.

What is claimed is:

1. A light emitting display, comprising:
a nitride light emitting diode formed on a first substrate; and
a thin film transistor formed on a second substrate which is spaced from the first substrate, the nitride light emitting diode and the thin film transistor being located between the first substrate and the second substrate;
wherein the first substrate and the second substrate are arranged face-to-face, and the nitride light emitting diode electrically connects with the thin film transistor, the thin film transistor comprises an active layer, and the active layer of the thin film transistor deviates from a light path of the nitride light emitting diode.

2. The light emitting display of claim 1, wherein the first substrate and the second substrate are made of sapphire, silicon, silicon on glass (SOG), glass, GaN, ZnO, or plastic.

3. The light emitting display of claim 2, wherein the first substrate is made of sapphire or silicon on glass, and the second substrate is made of glass.

4. The light emitting display of claim 1, wherein a first buffer layer is formed on the first substrate and the nitride light emitting diode is formed on the first buffer layer.

5. The light emitting display of claim 1, wherein a second buffer layer is formed on the second substrate and the thin film transistor is formed on the second buffer layer.

6. The light emitting display of claim 1, wherein a first buffer layer is formed on the first substrate, a second buffer layer is formed on the second substrate, the first buffer layer and the second buffer layer are electrically insulating layers, the first buffer layer and the second buffer layer are made of low temperature AlGaInN (LT-AlGaInN), SiC, SiOₓ, SiNₓ, SiON, HfOₓ, AlOₓ, TaOₓ, or BaSrTiOₓ.

7. The light emitting display of claim 1, wherein the nitride light emitting diode comprises an n-type semiconductor layer formed on the first substrate, a light emitting layer formed on the n-type semiconductor layer, a p-type semiconductor layer formed on the light emitting layer, a contact layer formed on the p-type semiconductor layer, a current spreading layer formed on the contact layer, a p-type electrode formed on the current spreading layer, and an n-type electrode located at a lateral side of the n-type semiconductor layer.

8. The light emitting display of claim 7, wherein the light emitting layer is made of AlₓGa_{y}In_{(1-x-y)}N (0≦x≦1, 0≦y≦1).

9. The light emitting display of claim 7, wherein the nitride light emitting diode emits light with a wavelength ranged from 300 nm to 550 nm.

10. The light emitting display of claim 1, wherein the thin film transistor comprises a gate electrode, a source electrode and a drain electrode, an insulation layer is formed on the gate electrode, the active layer is formed on the insulation layer, and the source electrode and the drain electrode are formed on the active layer.

11. The light emitting display of claim 1, wherein the active layer is a photosensitive semiconductor active layer which is made of oxide semiconductor.

12. The light emitting display of claim 11, wherein the photosensitive semiconductor active layer is made of InGaZnO, InZnHfO, InZnZrO, InZnSnO, InZnO, or AlInZnO

13. The light emitting display of claim 11, wherein the photosensitive semiconductor active layer comprises at least one element of In, Ca, Al, Zn, Cd, Ca, Mo, Sn, Hf, Cu, Ti, Ba and Zr.

14. The light emitting display of claim 1, wherein the nitride light emitting diode electrically connects with the thin film transistor via a connecting layer, and the connecting layer electrically connects one of a p-type electrode and an n-type electrode of the nitride light emitting diode to one of a source electrode and a drain electrode of the thin film transistor.

15. The light emitting display of claim 14, wherein the connecting layer is a conductive connecting layer and the conductive connecting layer is made of metal, conductive oxides, conductive glue, solder or a combination thereof.

16. The light emitting display of claim 15, wherein the connecting layer is a multilayer structure and the multilayer structure comprises a metal layer and a transparent conductive oxide layer.

17. The light emitting display of claim 15, wherein the connecting layer is made of silver colloid, SnBi, SnBiCu, SnBiTe, SnBiSe, BiSbTe, BiTeSe, or SnAgCu.

18. The light emitting display of claim 17, wherein the metal layer is made of a metal selected from In, Ca, Al, Zn, Cr, Ni, Mo, Sn, Ag, Au, Cu, Ti, Bi, Co, or an alloy thereof.

19. The light emitting display of claim 16, wherein the transparent conductive oxide layer is made of a material selected from InSnO, ZnSnO, InZnO, AlZnO, InZnSnO, InGaZnO, InZnHfO, InZnZrO, or a combination thereof.

20. The light emitting display of claim 7 further comprises a phosphor layer, wherein the phosphor is arranged inside of the light emitting display.

21. The light emitting display of claim 20, wherein the phosphor layer is arranged between the connecting layer and the current spreading layer of the nitride light emitting diode, the p-type electrode is formed at opposite ends of the current spreading layer, and the p-type electrode connects with the connecting layer.

22. The light emitting display of claim 1 further comprises a phosphor layer, wherein the phosphor layer is arranged outside of the light emitting display.

23. The light emitting display of claim 22, wherein the phosphor layer is located at an outer surface of the first substrate or the phosphor layer is located at an outer surface of the second substrate.

24. The light emitting display of claim 20, wherein the phosphor layer is located at a light path of the nitride light emitting diode to absorb the light emitted from the nitride light emitting diode and converts the light to another light with another wavelength.

25. The light emitting display of claim 1, wherein the thin film transistor comprises a metal electrode and the metal electrode is arranged on at least one of the source electrode and the drain electrode.

26. The light emitting display of claim 25, wherein one of the source electrode and the drain electrode comprises a metal column, and the metal column electrically connects one of the source electrode and the drain electrode to a p-type electrode or an n-type electrode of the nitride light emitting diode.
